(19) United States
(12) Patent Application Publication
(10) Pub. No.: US 2015/0226820 A1
(43) Pub. Date: Aug. 13, 2015

(54) Magnetic Resonance Imaging with Whole Body and Local Coil Systems

(71) Applicants: Stephan Biber, Erlangen (DE); Jürgen Nistler, Erlangen (DE); Thorsten Speckner, Erlangen (DE)

(72) Inventors: Stephan Biber, Erlangen (DE); Jürgen Nistler, Erlangen (DE); Thorsten Speckner, Erlangen (DE)

(21) Appl. No.: 14/620,666

(22) Filed: Feb. 12, 2015

(30) Foreign Application Priority Data
Feb. 12, 2014 (DE) 102014202567.2

(51) Int. Cl. G01R 33/483; G01R 33/34; G01R 33/383; G01R 33/44; G01R 33/54

(52) U.S. Cl. CPC G01R 33/4831; G01R 33/443; G01R 33/543; G01R 33/546; G01R 33/383; G01R 33/34092

(57) ABSTRACT

A magnetic resonance imaging system includes an arrangement of magnet systems for generating a homogeneous main magnetic field and additional gradient fields for spatial encoding. At least one transmission coil is used to radiate in an alternating electromagnetic field in order to induce magnetic resonance signals and measure the latter using at least one reception coil. The magnetic resonance imaging system is configured in such that, during an imaging measurement of the magnetic resonance signals for generating the alternating electromagnetic field, at least one fixedly installed whole body coil system and at least one mobile local coil system are operated simultaneously with separately actuated channels.

This application claims the benefit of DE 102014202567.2, filed on Feb. 12, 2014, which is hereby incorporated by reference in its entirety.

### FIELD

The disclosed embodiments relate to magnetic resonance imaging (MRI).

### BACKGROUND

Modern MRI systems operate with coil elements for emitting radio frequency pulses for exciting nuclear resonance and/or for receiving induced magnetic resonance signals. An MRI system usually includes a permanent magnet or a superconducting coil for generating a main magnetic field that is as homogeneous as possible in an examination region, at least one large whole body coil installed in the MRI system, and at least one mobile local coil arranged in a region of interest to generate an image with high contrast. To read out electromagnetic signals and frequencies from which images of a patient may be generated, magnetic field gradients are generated along three axes using gradient coils. The magnetic field gradients provide a spatial encoding via frequency and phase information.

To excite the magnetic dipoles disposed in the examination object to emit the MR signals, local coils may be used in addition to the whole body coil. Here, images with a high signal-to-noise ratio of the selected regions of interest are obtained. To this end, higher B₁ peak values and higher B₁ average values may be obtained using the local coils. Applications relying on very high B₁ values in a very short time may profit from the higher B₁ peak values. By way of example, this aids in the suppression of artifacts at implants and in spectroscopy. Moreover, such local coils used for transmission may be useful because the specific absorption rate (SAR) in relation to the whole patient remains low since—in contrast to the use of the whole body coil—only a dedicated part of the body is affected by the small transmission field. Moreover, the restriction of the transmission field permits targeted influencing of the field profile, as a result of which an improved protocol design with respect to the direction of the phase encoding is made possible and convolutions from other body parts, which are not being examined, may be suppressed more strongly. By way of example, a phase encoding direction in the z-direction may be achieved with less phase oversampling in knee or head imaging since the radiation by a local coil in the z-direction is lower for the knee or head region.

However, due to mutual influencing of whole body and local coils, only one of the coil variants may be operated at a time because otherwise artifacts are produced during image generation.

### SUMMARY AND DESCRIPTION

The scope of the present invention is defined solely by the appended claims and is not affected to any degree by the statements within this summary.

The present embodiments may obviate one or more of the drawbacks or limitations in the related art. For example, the disclosed embodiments may provide a method for generating magnetic resonance recordings and an MRI system with a transmitting whole body coil system and at least one transmitting local coil system.

The disclosed embodiments include a method for generating magnetic resonance recordings using an MRI system including an arrangement of magnet systems for generating a homogeneous main magnetic field and additional gradient fields for spatial encoding, in which at least one transmission coil is used to radiate in an alternating electromagnetic field in order to induce magnetic resonance signals and measure the magnetic resonance signals using at least one reception coil. Furthermore, the disclosed embodiments also include an MRI system for generating magnetic resonance recordings of an examination object, including an arrangement of magnet systems for generating a homogeneous main magnetic field and additional gradient fields for spatial encoding, an arrangement of transmission coils for generating an alternating electromagnetic field for inducing magnetic resonance signals (MR signals), at least one reception coil in order to measure the MR signals emitted by the examination object, and a computer system with control electronics, including a storage medium for storing computer programs that, during operation, control the MRI system and evaluate the measured MR signals. The control electronics include at least two separately controllable channels for transmission coils and at least one channel is connected to at least one fixedly installed whole body coil system and at least one channel is connected to at least one mobile local coil system.

Both the transmitting whole body coil systems, which are fixedly installed in the MRI system, and the mobile local coil systems, may be operated simultaneously if these systems are operated with separate control channels at the same time. On the one hand, this may provide (e.g., ensure) an individual actuation of the transmission coils with respect to amplitude and phase prior to the measurement such that, overall, a homogeneous B₁ alternating field is generated. However, on the other hand, it is also possible to operate the at least two channels with different transmission pulse forms with multi-channel transmission (pTX) actuation to achieve a homogeneous signal intensity of the MR signals, in which there simultaneously is a variation in the gradient field. This pTX method is described in Katscher et al., Magnetic Resonance in Medicine, 49:144-150 (2003).

The method generates magnetic resonance recordings using a magnetic resonance imaging system including an arrangement of magnet systems for generating a homogeneous main magnetic field and additional gradient fields for spatial encoding, in which at least one transmission coil is used to radiate in an alternating electromagnetic field in order to induce magnetic resonance signals and measure the magnetic resonance signals using at least one reception coil. During an imaging measurement of the magnetic resonance signals for generating the alternating electromagnetic field, at least one fixedly installed whole body coil system and at least one mobile local coil system are operated simultaneously with separately actuated channels.

With separate actuation of the channels, the transmission coils connected to the separate channels may be operated and, at least in part, also are operated individually with respect to the power, amplitude and phase of the supply AC voltage. However, the supply frequency for the alternating B₁ field to be generated remains the same over all channels.

As a result of this type of operation of an MRI system, the transmission coils of the whole body coil system, which may be actuated using one or two channels, are additionally supported by local transmission coils of the mobile local coil system such that the excitation quality in situations, for example, in which individual body parts or extremities are otherwise poorly irradiated, is improved. Significantly less transmission power is required as a result of the local effect of the local transmission coil systems relative to fixedly installed whole body coils. Therefore the SAR in relation to the whole examination object is favorable and a cost-effective implementation in existing MRI systems is made possible.

The method may be configured such that the at least one whole body coil system is operated with a plurality of separately actuated channels and/or that the at least one local coil system is operated with a plurality of separately actuated channels. However the local coil system may be actuated by a plurality of channels in this case since the positioning of the local coil systems, which changes in each examination, may be compensated for.

In accordance with a separate actuation of the transmission coils, the magnetic field generated by the transmission coils may be homogenized prior to the imaging measurement. By way of example, the alternating electromagnetic field may also be homogenized at least through variation of the amplitude and phase of the actuation of the individual transmission coils in the local coil systems. The frequency control of the transmission coils by the individual channels then merely differs by a complex factor or a complex number.

However, the alternating electromagnetic field may be homogenized, either alternatively or in a complementary manner, through variation of the amplitude and phase of the actuation of individual coils in the whole body coil system.

Instead of homogenization of the alternating electromagnetic field implemented prior to the actual measurement, the at least two channels of the transmission coils may be operated with different pulse forms to achieve a homogeneous deflection of the spins, e.g., in order to homogenize the signal intensity of the MR signals, in which there may also be a variation of at least one of the gradient fields in the x-, y- or z-direction at the same time. The magnetization of the spins in the examination object becomes homogeneous, e.g., the spins experience the same deflection, e.g., the same flip angle, and therefore a homogeneous excitation is achieved in the imaging sequence.

The method of homogenizing the alternating electromagnetic field may be combined with the influencing of the transmission pulse form and the simultaneous adaptation of the gradient field.

An MRI system for generating magnetic resonance recordings of an examination object includes an arrangement of magnet systems for generating a homogeneous main magnetic field and additional gradient fields for spatial encoding, an arrangement of transmission coils for generating an alternating electromagnetic field for inducing a magnetic resonance signal, at least one reception coil in order to measure the MR signals emitted by the examination object, and a computer system with control electronics, including a storage medium for storing computer-readable code (or instructions) that, during operation (e.g., execution by a processor), control the MRI system and evaluate the measured MR signals. The control electronics include at least two separately controllable channels for transmission coils and at least one channel is connected to at least one fixedly installed whole body coil system and at least one channel is connected to at least one mobile local coil system.

The computer-readable code (or instructions) stored in the computer system of the MRI system and executed during operation simultaneously operates the channels of the whole body coil system and the channels of the at least one local coil system.

The whole body coil system may include at least two individual coils that are respectively connected to a separately controlled channel. Alternatively or additionally, at least one local coil system may include a plurality of individual coils that are connected to a plurality of separately actuated channels.

Furthermore, the MRI system may include computer-readable code (or instructions) stored in the computer system of the MRI system that executes the above-described method during operation.

### BRIEF DESCRIPTION OF THE DRAWINGS

FIG. 1 shows an MRI system with simultaneously actuated whole body coil and local coil systems.

FIG. 2 is a schematic view of an arrangement of transmission coils of an MRI system in accordance with one embodiment.

FIG. 3 is a cross sectional view of a patient supported on a patient couch of an MRI system having a local coil in accordance with the arrangement of FIG. 2.

FIG. 4 is a schematic view of an arrangement of transmission coils of an MRI system in accordance with one embodiment.

### DETAILED DESCRIPTION

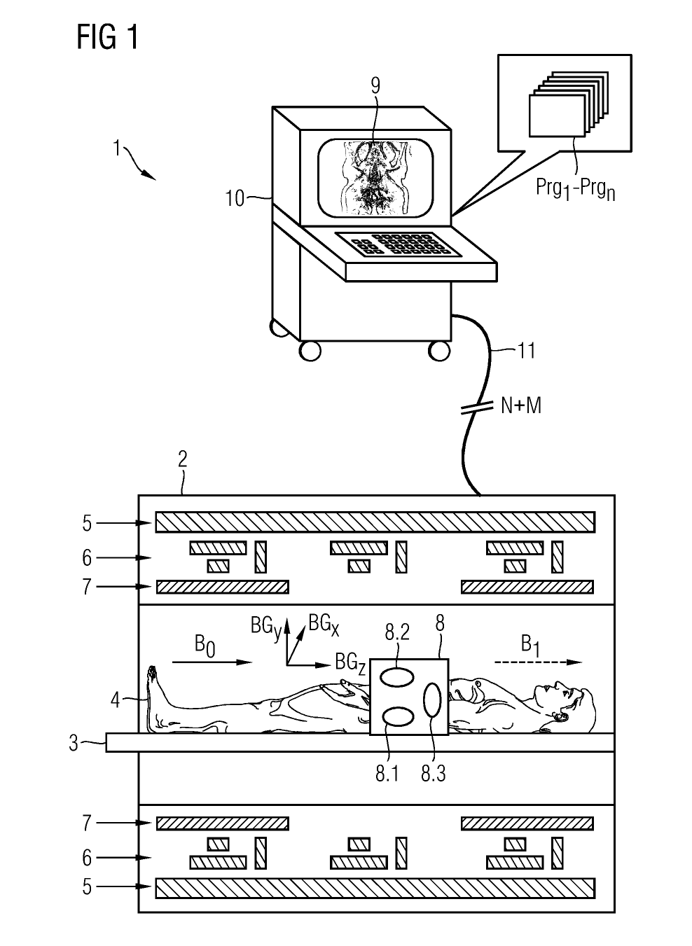

FIG. 1 shows a schematic illustration of an MRI system 1 including a housing 2, in which a patient couch 3 with a patient 4 is disposed for an MRI examination. Arranged in the housing 2 are magnet systems of an MRI system, which include a main magnet 5 that generates a largely homogeneous magnetic field B₀ in the measurement region of the MRI system. Gradient fields in three main directions BGₓ, BG_{y}, BG_{z} are generated by additional gradient magnet systems 6 for spatial encoding of the induced MR signals. A whole body coil system 7 fixedly installed in the housing and, a mobile local coil system 8, which includes a plurality of individual coils 8.1 to 8.3, generate an alternating electromagnetic field B₁ that induces the MR signals in the patient. In the depicted example, the local coil system 8 is arranged in the region of the abdomen of the patient 4 since this region is of interest in the present case. Other regions may also be equipped with appropriately designed local coil systems. Alternatively, a plurality of regions may simultaneously be equipped with local coil systems.

A computer system 10 is connected to the magnet systems and coils 5-8 via a multiplicity of control and data lines 11, and provided for controlling the MRI system 1, including the evaluation and reconstruction of MR recordings 9. The computer system 10 includes at least one channel for controlling the whole body coil system 7 and, additionally, at least one further channel for controlling the mobile local coil system 8. The channels generate the alternating electromagnetic field B₁ during simultaneous operation. In the example shown here, the whole body coil system includes two individual coils, and so, in this example, two (N) channels are used in the computer system 10 for the control. The local coil system additionally includes three individual coils 8.1 to 8.3, and so, in this example, three (M) additional channels are included in the computer system for the actuation. Therefore, overall, the computer system 10 includes at least five (N+M) control channels for individual actuation of the transmission coils.

In order to operate the MRI system 1, including the actuation of the magnetic coil systems and also for the analysis of the MR signals with the reconstruction of the MRI recordings, the computer system 10 includes a storage medium on which computer-readable code or instructions in the form of a multiplicity of computer programs Prg₁-Prgₙ are stored. These computer programs Prg₁-Prgₙ are also used to execute the method during operation of the MRI system.

As a result of the possibility for individual actuation of the transmission coils, the alternating electromagnetic field B₁ generated by these coils may be homogenized by appropriate adaptation of oscillation amplitudes and phases of the individual coils. An adaptation of the local coils 8.1 to 8.3 may be undertaken to that end. The power of the local coils may remain low—relative to the power of the whole body coils—due to the vicinity of the local coils to the region to be examined. Secondly, the individual actuation of the transmission coils may, in an alternative or complementary manner, also be used to influence the pulse form thereof and, in a complementary manner, simultaneously also modify the gradient fields such that, overall, an MR signal as regular as possible is induced over the measurement region.

A combination of both variants may be provided, in which B₁ homogenization (e.g., B₁ shimming) is initially performed, followed during the measurement by a change in the pulse form in the transmission coils when generating the alternating electromagnetic field B₁ while simultaneously varying at least one gradient field in time.

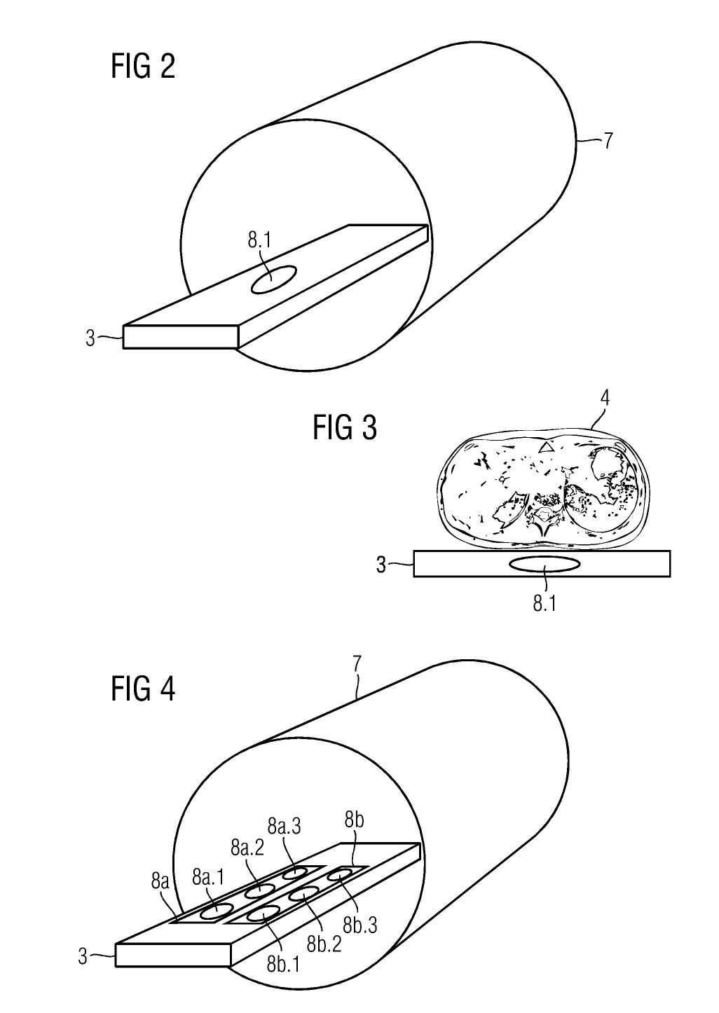

Another variant of an arrangement of the simultaneously operated whole body coil system and local coil system is depicted in FIG. 2. Here, the patient couch 3 with a local coil 8.1 housed therein may be seen in a schematic illustration. Here, the whole body coil system 7 is operated via one- or two-channel actuation while the local coil 8.1 is actuated over one channel. This arrangement may be useful for examining and depicting the bodies of vertebrae, as may be seen from the sectional illustration of FIG. 3, taken along lines through the patient couch 3 and the abdomen of the patient 4 shown in FIG. 2.

Another, further variant of the arrangement of local coil systems 8a and 8b, operated simultaneously with the whole body coil system, is depicted in FIG. 4. Here, two parallel local coil systems 8a and 8b with respectively three individual coils 8a.1, 8a.2, 8a.3 and 8b.1, 8b.2, 8b.3 arranged in a staggered manner along the z-direction are shown in the patient couch 3. The individual transmission coils 8a.1, 8a.2, 8a.3 and 8b.1, 8b.2, 8b.3 are respectively actuated by dedicated channels and so are able, over a relatively large examination region, to influence and correct any excesses or holes present in the B1 field.

It is to be understood that the elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent, and that such new combinations are to be understood as forming a part of the present specification.

While the present invention has been described above by reference to various embodiments, it should be understood that many changes and modifications may be made to the described embodiments. It is therefore intended that the foregoing description be regarded as illustrative rather than limiting, and that it be understood that all equivalents and/or combinations of embodiments are intended to be included in this description.

1. A method for generating magnetic resonance recordings using a magnetic resonance imaging system, the method comprising:
generating, via an arrangement of magnet systems, a homogeneous main magnetic field and gradient fields for spatial encoding;
generating, via at least one transmission coil, an alternating electromagnetic field to induce magnetic resonance signals; and
measuring the magnetic resonance signals with at least one reception coil;
wherein generating the alternating electromagnetic field comprises operating at least one fixedly installed whole body coil system and at least one mobile local coil system simultaneously with separately actuated channels.

2. The method of claim 1, wherein operating the at least one whole body coil system comprises operating the at least one whole body coil system with a plurality of separately actuated channels.

3. The method of claim 1, wherein operating the at least one local coil system comprises operating the at least one local coil system with a plurality of separately actuated channels.

4. The method of claim 1, wherein generating the alternating electromagnetic field further comprises, prior to measuring the magnetic resonance signals, varying actuation of the at least one transmission coil to homogenize the magnetic field.

5. The method of claim 4, wherein the at least one mobile local coil system comprises individual coils, and wherein varying the actuation comprises varying amplitude and phase of the actuation of the individual coils in the at least one mobile local coil system.

6. The method of claim 4, wherein the at least one whole body coil system comprises individual coils, and wherein varying the actuation comprises varying amplitude and phase of the actuation of the individual coils in the at least one whole body coil system.

7. The method of claim 1, wherein operating the at least one fixedly installed whole body coil system and at least one mobile local coil system comprises operating the separately actuated channels with different transmission pulse forms such that a homogeneous deflection of spins is achieved.

8. The method of the claim 7, wherein generating the gradient fields comprises varying simultaneously at least one of the gradient fields.

9. A magnetic resonance imaging (MRI) system for generating magnetic resonance recordings of an examination object, the MRI system comprising:
an arrangement of magnet systems to generate a homogeneous main magnetic field and gradient fields for spatial encoding;
an arrangement of transmission coils to generate an alternating electromagnetic field for inducing a magnetic resonance signals;
at least one reception coil to measure the magnetic resonance signals emitted by the examination object; and
a computer system comprising control electronics and a storage medium in which computer-readable instructions are stored for execution by the computer system to control the MRI system and evaluate the measured magnetic resonance signals;
wherein the control electronics comprise at least two separately controllable channels for the transmission coils;
wherein the at least two separately controllable channels comprise at least one channel connected to at least one fixedly installed whole body coil system and at least one channel connected to at least one mobile local coil system; and
wherein the execution of the computer-readable instructions simultaneously operates the at least one channel of the at least one fixedly installed whole body coil system and the at least one channel of the at least one mobile local coil system.

10. The MRI system of claim 9, wherein the at least one fixedly installed whole body coil system comprises at least two individual coils, each of which is respectively connected to a separately controlled channel of the at least two separately controllable channels.

11. The MRI system of claim 9, wherein the at least one mobile local coil system comprises a plurality of individual coils, each of which is connected to a respective one of a plurality of separately actuated channels of the at least two separately controllable channels.

12. The MRI system of claim 9, wherein the execution of the computer-readable instructions controls the MRI system to:
generate, via the arrangement of magnet systems, a homogeneous main magnetic field and gradient fields for spatial encoding;
operate the at least one fixedly installed whole body coil system and the at least one mobile local coil system simultaneously with separately actuated channels to generate, via the arrangement of transmission coils, an alternating electromagnetic field to induce magnetic resonance signals.

13. The MRI system of claim 9, wherein:
the at least one fixedly installed whole body coil system comprises at least two individual coils, each of which is respectively connected to a separately controlled channel of the at least two separately controllable channels; and
the at least one mobile local coil system comprises a plurality of individual coils, each of which is connected to a respective one of a plurality of separately actuated channels of the at least two separately controllable channels.

14. The method of claim 1, wherein operating the at least one whole body coil system and the at least one mobile local coil system comprises:
operating the at least one whole body coil system with a first plurality of separately actuated channels; and
operating the at least one local coil system with a second plurality of separately actuated channels.

15. The method of claim 14, wherein generating the alternating electromagnetic field further comprises, prior to measuring the magnetic resonance signals, varying actuation of the at least one transmission coil to homogenize the magnetic field.

16. The method of claim 15, wherein:
the at least one mobile local coil system comprises a first set of individual coils;
the at least one whole body coil system comprises a second set of individual coils;
varying the actuation comprises varying amplitude and phase of the actuation of the first set of individual coils in the at least one mobile local coil system; and
varying the actuation comprises varying amplitude and phase of the actuation of the second set of individual coils in the at least one whole body coil system.
